(19) United States
(12) Patent Application Publication
(10) Pub. No.: US 2025/0391671 A1
(43) Pub. Date: Dec. 25, 2025

(54) REACTION CHAMBER WITH MULTI PHASE PRECURSOR DELIVERY

(71) Applicant: Applied Materials, Inc., Santa Clara, CA (US)

(72) Inventors: Tien Tan, Campbell, CA (US); Ganesh Balasubramanian, Fremont, CA (US); Karthik Janakiraman, San Jose, CA (US); Juan Carlos Rocha-Alvarez, San Carlos, CA (US); Xinhai Han, Palo Alto, CA (US); Rui Cheng, San Jose, CA (US); Aydin Aykut, Sunnyvale, CA (US); Kelly Sweeney, Santa Clara, CA (US); Guangyan Zhong, Sunnyvale, CA (US); Xinyi Zhong, San Jose, CA (US)

(73) Assignee: Applied Materials, Inc., Santa Clara, CA (US)

(21) Appl. No.: 18/748,845

(22) Filed: Jun. 20, 2024

(51) Int. Cl. H01L 21/67; H01J 37/32

(52) U.S. Cl. CPC H01L 21/67017; H01J 37/32357; H01J 37/32449

(57) ABSTRACT

Exemplary semiconductor processing systems may include at least one processing chamber. Each of the at least one processing chamber may include a gas distribution assembly. The systems may include a gas panel that is fluidly coupled with each gas distribution assembly. The systems may include a remote precursor delivery system that is fluidly coupled with the gas panel. The remote precursor delivery system may include a precursor source associated with a non-gaseous precursor. The precursor source may be operable to generate a vapor from the non-gaseous precursor. The remote precursor delivery system may include a flow controller that is operable to control a flow of the vapor to the gas panel.

### TECHNICAL FIELD

The present technology relates to components and apparatuses for semiconductor manufacturing. More specifically, the present technology relates to precursor delivery systems and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Various precursors may originate as different phases of matter (e.g., gas, liquid, solid, etc.) prior to being delivered to different chambers for processing a substrate. This may require the substrate to be moved from one chamber to another, which results in the substrate breaking vacuum and reduces processing throughput.

Thus, there is a need for improved systems and methods that can be used to more efficiently produce high quality devices and structures. These and other needs are addressed by the present technology.

### SUMMARY

Exemplary semiconductor processing systems may include at least one processing chamber. Each of the at least one processing chamber may include a gas distribution assembly. The systems may include a gas panel that is fluidly coupled with each gas distribution assembly. The systems may include a remote precursor delivery system that is fluidly coupled with the gas panel. The remote precursor delivery system may include a precursor source associated with a non-gaseous precursor. The precursor source may be operable to generate a vapor from the non-gaseous precursor. The remote precursor delivery system may include a flow controller that is operable to control a flow of the vapor to the gas panel.

In some embodiments, the remote precursor delivery system may include a first remote precursor delivery system. The precursor source of the first remote precursor delivery system may include a solid-phase precursor source. The semiconductor processing system may include a second remote precursor delivery system that is fluidly coupled with the gas panel. The second remote precursor delivery system may include a precursor source associated with a liquid precursor. The precursor source of the second remote precursor delivery system may be operable to generate a vapor from the liquid precursor. The second remote precursor delivery system may include a flow controller that is operable to control a flow of the vapor from the liquid precursor to the gas panel. The remote precursor delivery system may include a concentration sensor that is operable to determine a concentration of the vapor being delivered to the gas panel. The remote precursor delivery system may include a controller that is operable to adjust one or both of a temperature and a pressure of the non-gaseous precursor based on the concentration of the vapor. The precursor source of the remote precursor delivery system may include a liquid-phase precursor source. The remote precursor delivery system may include a liquid flow controller that is fluidly coupled with the liquid-phase precursor source. The remote precursor delivery system may include a liquid vaporizer fluidly coupled with a downstream end of the liquid flow controller. The systems may include one or more heated delivery lines that fluidly couple the remote precursor delivery system with the gas panel. The systems may include one or more purge lines that fluidly couple the remote precursor delivery system with the gas panel. Each gas distribution assembly may include an output manifold. The gas panel may be fluidly coupled with each gas distribution assembly via a respective one of the output manifolds. The systems may include a remote plasma unit coupled with each gas distribution assembly. The gas panel may be fluidly coupled with each gas distribution assembly via the remote plasma unit.

Some embodiments of the present technology may encompass precursor delivery systems. The systems may include a gas panel that is operable to control delivery of one or more precursors to a substrate processing system. The systems may include a remote precursor delivery system that is fluidly coupled with the gas panel. The remote precursor delivery system may include a precursor source associated with a non-gaseous precursor. The precursor source may be operable to generate a vapor from the non-gaseous precursor. The remote precursor delivery source may include a flow controller that is operable to control a flow of the vapor to the gas panel.

In some embodiments, the remote precursor delivery system may include a first remote precursor delivery system. The precursor source of the first remote precursor delivery system may include a solid-phase precursor source. The precursor delivery system may include a second remote precursor delivery system that is fluidly coupled with the gas panel. The second remote precursor delivery system may include a precursor source associated with a liquid precursor. The precursor source of the second remote precursor delivery system may be operable to generate a vapor from the liquid precursor. The second remote precursor delivery system may include a flow controller that is operable to control a flow of the vapor from the liquid precursor to the gas panel. The first remote precursor delivery system, the second remote precursor delivery system, and the gas panel may be disposed within a same housing. The remote precursor delivery system and the gas panel may be disposed within different housings. The systems may include a controller that is operable to control a concentration and flow rate of the vapor.

Some embodiments of the present technology may encompass methods for delivering precursors to a processing chamber. The methods may include delivering a first vapor precursor to a processing chamber from a gas panel. The methods may include vaporizing a non-gaseous precursor to generate a second vapor precursor. The methods may include delivering the second vapor precursor to the gas panel from a remote precursor delivery system. The methods may include delivering the second vapor precursor to the processing chamber from the gas panel. A source of the first vapor precursor and the non-gaseous precursor may be in different phases of matter.

In some embodiments, the methods may include heating the second vapor precursor prior to delivering the second vapor precursor to the gas panel. The methods may include determining a concentration of the second vapor precursor being delivered to the gas panel. The methods may include adjusting one or both of a temperature and a pressure of the non-gaseous precursor based on the concentration of the second vapor precursor. The remote precursor delivery system may include a first remote precursor delivery system. The non-gaseous precursor may include a liquid precursor. The methods may include vaporizing a solid precursor to generate a third vapor precursor. The methods may include delivering the third vapor precursor to the gas panel from a second remote precursor delivery system. The methods may include delivering the third vapor precursor to the processing chamber from the gas panel. The first vapor precursor may be delivered to the processing chamber after the second vapor precursor. The first vapor precursor and the second vapor precursor may be delivered to the processing chamber sequentially. The first vapor precursor and the second vapor precursor may be delivered to the processing chamber simultaneously.

Such technology may provide numerous benefits over conventional systems and techniques. For example, embodiments of the present technology may enable different phases of precursors to be delivered to a single chamber environment. This may enable a larger variety of processing operations to be performed in a single chamber and may eliminate several substrate transferring steps, which may help increase throughput and efficiency. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary process chamber according to some embodiments of the present technology.

FIG. 3 shows a schematic block diagram of an exemplary processing system according to some embodiments of the present technology.

FIG. 4A shows a schematic diagram of an exemplary precursor delivery system according to some embodiments of the present technology.

FIG. 4B shows a schematic diagram of an exemplary precursor delivery system according to some embodiments of the present technology.

FIG. 5 shows exemplary operations in a method of delivering precursors according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Various semiconductor processing operations, such as deposition and etch operations, may utilize precursors that are provided as different phases of matter. For example, various precursor sources include precursors in gas, liquid, or solid forms. Regardless of the initial phase of matter, the various precursors may be delivered to processing chambers in vapor form. For example, liquid precursors may be vaporized, such as by applied heat, pressure, and/or vibration to the liquid to aerosolize or otherwise vaporize the liquid. Heat and/or pressure may be applied to solid precursors to melt and evaporate and/or to sublimate the solid precursor to generate a vapor form of the solid precursor. However, because of the different requirements to vaporize precursors of different phases of matter, each phase of precursor requires distinct equipment to vaporize the precursor and control the concentration/flow of the precursor to the processing chambers. Given the complexities of delivering precursors in various forms, conventional processing systems only use a single phase of precursor with a given chamber. As a result, when substrate processing requires steps utilizing precursors in different phases, the substrates are first processed using a precursor from a first phase of matter, transferred to a different chamber, and subsequently processed using a precursor from a second different phase of matter. While generally effective, such processes increase the number of processing/transfer steps and add complexity and time to the processing of the substrate, thereby reducing the throughput of the processing system. Additionally, the substrates may undergo undesired thermal cycling during transfer between different chambers.

The present technology addresses these issues by incorporating one or more remote precursor delivery systems into a gas panel or other gas delivery system for a single processing chamber (or related set of chambers). Each remote precursor delivery system may include components that may generate vapor from a non-gaseous precursor (e.g., a liquid or solid) and deliver the vapor precursor to the gas panel for subsequent delivery to the processing chamber. This enables the gas panel to facilitate delivery of any number of precursors that originate in any type of phase of matter to be delivered to a single chamber in vapor form and may enable any number and type of processing operations to be performed in a single chamber or set of chambers without the need to transfer the substrate between different chambers.

Although the remaining disclosure will routinely identify specific precursor delivery systems and processes utilizing the disclosed technology, it will be readily understood that the systems and methods are equally applicable to other deposition, etching, and cleaning chambers, as well as processes as may occur in the described chambers. Accordingly, the technology should not be considered to be so limited as for use with these specific deposition processes or chambers alone. The disclosure will discuss one possible system and chamber that may include precursor delivery systems according to embodiments of the present technology before additional variations and adjustments to this system according to embodiments of the present technology are described.

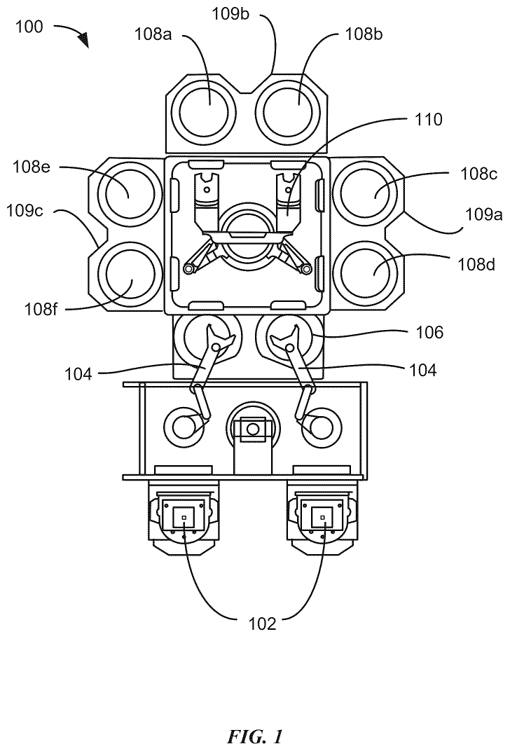

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

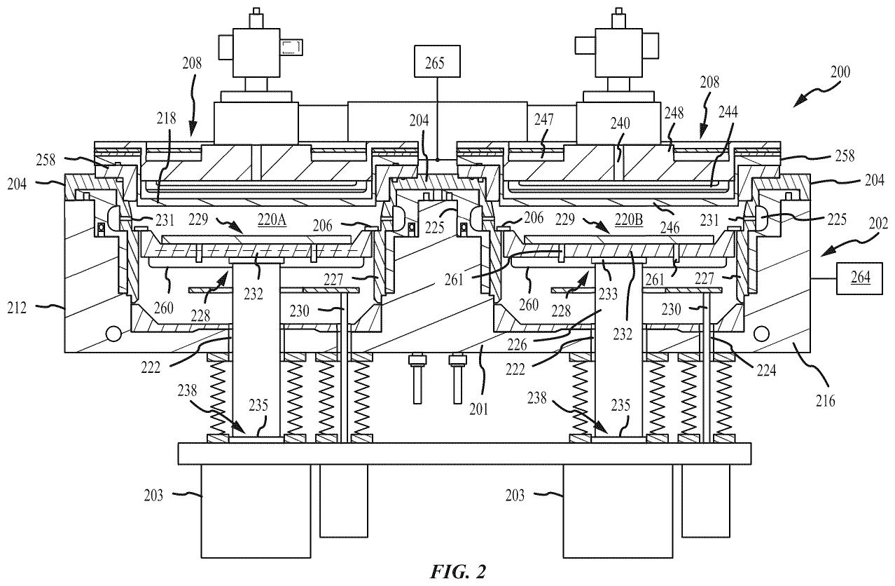

FIG. 2 shows a schematic cross-sectional view of an exemplary process chamber 200 according to some embodiments of the present technology. Process chamber 200 may illustrate a pair of processing chambers 108 that may be fitted in one or more of tandem sections 109 described above, and which may include substrate support assemblies according to embodiments of the present technology. The process chamber 200 generally may include a chamber body 202 having sidewalls 212, a bottom wall 216, and an interior sidewall 201 defining a pair of processing regions 220A and 220B. Each of the processing regions 220A-220B may be similarly configured and may include identical components.

For example, processing region 220B, the components of which may also be included in processing region 220A, may include a pedestal 228 disposed in the processing region through a passage 222 formed in the bottom wall 216 in the process chamber 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source 265 may provide power to multiple chambers, however in other embodiments one or more of the chambers may include a dedicated RF source 265. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional thermal channel 247 may be formed in the annular base plate 248 of the gas distribution system 208 to cool the annular base plate 248 during operation. A heat transfer fluid, such as water, ethylene glycol, a gas, or the like, may be circulated through the thermal channel 247 such that the base plate 248 may be maintained at a predefined temperature. In some embodiments, the heat transfer fluid may be used to heat the lid 204 and/or associated components. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the chamber 200.

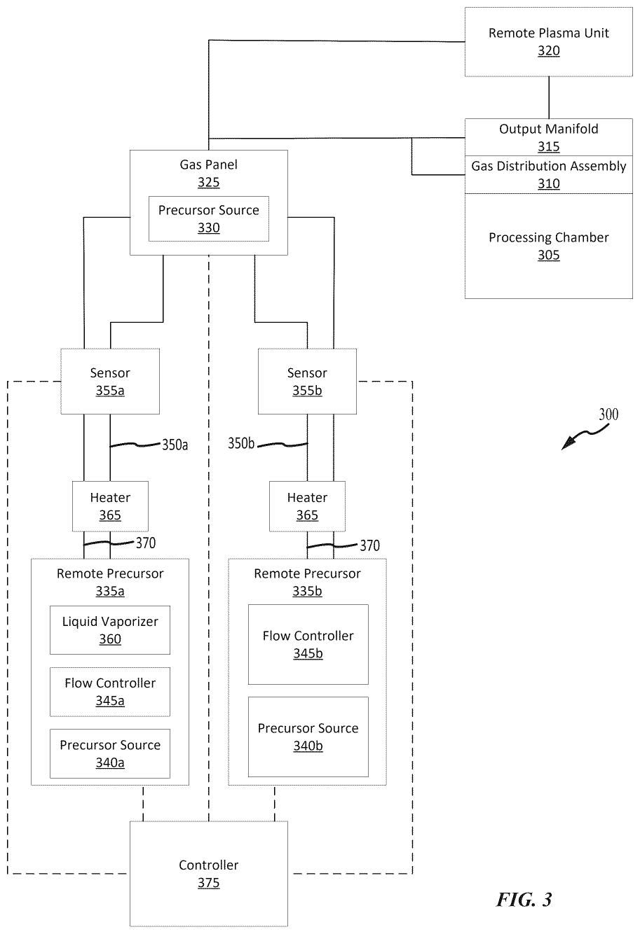

FIG. 3 shows a schematic block diagram of an exemplary semiconductor processing system 300 according to some embodiments of the present technology. FIG. 3 may include one or more components discussed above with regard to FIG. 2. For example, processing system 300 may include at least one processing chamber 305. While shown with a single chamber 305, it will be appreciated that any number of processing chambers 305 may be included with system 300. Each chamber 305 may be the same and may receive a common or different recipe of precursors. Each processing chamber 305 may be used to perform semiconductor processing operations including deposition and/or etching of stacks of dielectric materials as previously described. Each processing chamber 305 may be similar to chamber 200 and may include any of the features described in relation to chamber 200. It will be appreciated that each chamber 305 may take other forms and may include other chambers for performing deposition, etch, clean, and/or other operations known in the art. Each chamber 305 may include a gas distribution assembly 310, which may control delivery and distribution of precursors and/or plasmas generated using such precursors and/or other gases to a processing region of the chamber 305. The gas distribution assemblies 310 may include, without limitation, one or more gas boxes, blocker plates, diffusers, faceplates, showerheads, and/or other components that form a portion of a lid stack of a given chamber 305.

System 300 may include a gas panel 325 and/or other gas delivery system that may be fluidly coupled with each of the processing chambers 305 and that deliver one or more precursors in gaseous form to the gas distribution assemblies 310. Gas panel 325 may be coupled directly with each gas distribution assembly 310 or may be coupled with each gas distribution assembly 310 via one or more intervening components. For example, each chamber 305 and/or gas distribution assembly 310 may include an output manifold 315 that receives gaseous precursors from gas panel 325 and delivers the gaseous precursors to downstream components of the respective gas distribution assembly 310. In some embodiments, system 300 may include a remote plasma unit 320 that may receive gaseous precursors from gas panel 325, remotely generate (e.g., remote from a processing region of chambers 305) a plasma from the precursors, and supply the plasma to the processing region of one or more chambers 305. In some embodiments, system 300 may include both output manifolds 315 and remote plasma unit 320, however other embodiments may include only one or neither of output manifolds 315 and remote plasma unit 320.

Each gas panel 325 may include a number of components that may control the mixing and flow of one or more gaseous precursors. For example, each gas panel 325 may include a number of valves, mass flow controllers, and/or other components that may enable the flow of one or more gaseous precursors to be controlled for delivery to one or more chambers 305. Each gaseous precursor may be provided to gas panel 325 using a precursor source 330. In some embodiments, precursor sources 330 may include a gas precursor source, such as a pressurized container of a precursor in a gaseous form. In other embodiments, one or more precursor sources may be provided in the form of a remote precursor delivery system 335 that is fluidly coupled with gas panel 325. Each remote precursor delivery system 335 may be used to provide a non-gaseous precursor to gas panel 325 in a gaseous phase. For example, each remote precursor delivery system 335 may be operable to generate a vapor from a non-gaseous precursor and deliver the vapor to gas panel 325 for subsequent mixing and/or deliver to chambers 305. System 300 may include any number of remote precursor deliver systems 335. For example, system 300 may include a single remote precursor delivery system, two or more remote precursor delivery systems, three or more remote precursor delivery systems, four or more remote precursor delivery systems, five or more remote precursor delivery systems, ten or more remote precursor delivery systems, or more.

Each remote precursor delivery system 335 may include a precursor source 340 that contains and is associated with a non-gaseous precursor. Each precursor source 340 may be operable to generate a vapor from the non-gaseous precursor. For example, each precursor source 340 may include temperature and/or pressure modulation devices that may adjust parameters associated with vaporizing the non-gaseous precursor. Each remote precursor delivery system 335 may include a flow controller 345 that is operable to control a flow of the vapor to gas panel 325, such as via one or more delivery lines 350. The arrangement and form of each precursor source 340 and/or flow controller 345 may depend on the type of non-gaseous precursor being utilized. For example, for a solid-phase precursor, precursor source 340a of remote precursor delivery system 335a may include one or more components that control a temperature and/or pressure within a chamber in which the solid-phase precursor is stored. The temperature and/or pressure may be modulated based on signals from one or more controllers, which may adjust a rate at which the solid-phase precursor is vaporized. For example, conditions within the chamber may be carefully controlled to control the rate of melting/evaporation and/or sublimation of the solid-phase precursor to generate a vapor from the precursor. A flow controller 345a may be used to control a flow of the vapor from precursor source 340a to gas panel 325. In some embodiments, system 300 may include one or more concentration sensors 355a that may detect a concentration of the vapor within the solid-phase precursor chamber and/or within delivery line 350a. Based on the detected concentration, the controller may adjust the temperature and/or pressure within the solid-phase precursor chamber of precursor source 340a and/or a flow rate of flow controller 345a to ensure that a proper molar volume of vapor is delivered to gas panel 325 for subsequent delivery to chambers 305.

For a liquid-phase precursor, remote precursor delivery system 335b may include precursor source 340b that may include a storage volume that holds a precursor in a liquid-phase. The precursor may be stored within precursor source 340b at room temperature and pressure and/or may be stored at a different temperature and/or pressure. Precursor source 340b may be fluidly coupled with liquid flow controller 345b, which may include one or more valves that enable liquid flow controller 345b to selectively control the flow of liquid from precursor source 340b to downstream components of system 300. Remote precursor delivery system 335b may include a liquid vaporizer 360 that is fluidly coupled with a downstream end of liquid flow controller 345b, such as using one or more liquid supply lines. Using one or more valves, liquid flow controller 345b may selectively control a flow rate and/or flow volume of liquid, if any, that is delivered to liquid vaporizer 360. Liquid that is supplied to liquid vaporizer 360 may be vaporized into a gas that is transportable to one or more processing chambers 305. For example, in some embodiments liquid vaporizer 360 may heat the liquid to a temperature that is sufficiently high so as to vaporize the liquid. In other embodiments, liquid vaporizer 360 may vibrate the liquid, introduce the liquid into a gaseous carrier stream, and/or alter a pressure of the liquid to generate a vapor from the liquid-phase precursor. Liquid vaporizer 360 may be any kind of vaporizing unit, such as a bubbler, a flash vaporizer, a direct liquid injection vaporizer, and/or other types of vaporizer (which may or may not use carrier gases).

The gas generated by vaporizer 360 may be delivered to gas panel 325 via delivery lines 350b. In some embodiments, one or more sensors 355b, such as pressure sensors and/or concentration sensors, may be used to monitor the flow of vapor and/or concentration of the precursor within the vapor from precursor source 340b. For example, the vapor may be passed to a line pressure sensor and/or manometer, which may monitor a pressure of the vapor within delivery line 350b. Similarly, a concentration sensor may be provided within delivery line 350b to measure a concentration of liquid-phase precursor within the vapor. One or more controllers may be used to adjust a vaporization rate of liquid vaporizer 360 (e.g., via adjustments to one or more of temperature, pressure, carrier gas rate, vibration rate, etc.) and/or a flow rate through liquid flow controller 345b to control a rate and/or concentration of vapor delivered to gas panel 325 via delivery line 350b.

In some embodiments, delivery lines 350 may include heaters 365 and/or heater jackets that may heat the vaporized precursors prior to delivery to gas panel 325. Heater 365 may be a gas heater and/or an electrical heater that is disposed about and/or otherwise in contact with delivery lines 350 and/or other component of system 300. In a particular embodiment, heater 365 may be a block heater that is disposed about a portion of a calibration block of system 300, although various other forms of heaters may be used in other embodiments. In some embodiments, all or a portion of delivery lines 350 may be insulated and/or actively heated, such as by using wrap insulation and/or a heater jacket. In some embodiments, the entire length of delivery lines 350 may be covered by insulation and/or a heater jacket.

In some embodiments, prior to being delivered to processing chambers 305, gases from precursor source 330 and/or remote precursor delivery systems 335 may be mixed with one or more other gases and/or precursors, including gases and/or precursors provided from different sources (e.g., vapors supplied from one or more remote precursor delivery systems 335 may be mixed together and/or mixed with gas from one or more precursor sources 330). The mixing of the gases may occur within gas panel 325, such as using one or more gas blocks and/or may be mixed at one or more components interfaced between gas panel 325 and processing chambers 305. The gases may include cleaning gases, purge gases, plasma-generating precursors, and/or other types of process gases using in semiconductor fabrication operations. In some embodiments, each remote precursor delivery system 335 may include one or more purge lines 370, which may be used to deliver purge gases, such as argon, to gas panel 325, chambers 305, and/or other intervening components. In some embodiments purge lines 370 may be heated in a manner similar to delivery lines 350.

System 300 may include one or more controllers 375, which may control the operations of various gas delivery components of system 300. For example, controllers 375 may be used to control actuation of gas panel 325 (e.g., the valves, mass flow controllers, etc.), remote plasma unit 320, and remote precursor delivery systems 335 (e.g., precursor sources 340 and/or flow controllers 345). Controllers 375 may be communicatively coupled with sensors 355, which may enable controllers 375 to operate remote precursor delivery systems 335 on a feedback loop to precisely control a molar volume and/or other rate of delivery of precursor to gas panel 325 and/or chambers 305 by adjusting operation of precursor sources 340 and/or flow controllers 345 based on concentration, pressure, and/or other data from sensors 355. In some embodiments, controllers 375 may include a system level controller that controls operations of one or more components of system 300. In other embodiments, each component of system 300 may include a dedicated controller 375. As just one example, remote plasma unit 320, gas panel 325, each remote precursor delivery system 335, and/or component thereof may include a dedicated controller 375 that may control operation of the particular component or set of components. For example, controllers 375 may control a concentration of precursor within a vapor (e.g., by controlling parameters such as temperature, pressure, vibration rate, carrier gas flow rate, etc.) of a component of a remote precursor delivery system 335 that generates a vapor from a non-gaseous precursor, a flow rate of a liquid or vapor (e.g., using a flow controller 345 and/or a mass flow controller and/or valve of gas panel 325), mixing rate of one or more gases within gas panel 325, and/or other parameters of the various precursors. Controllers 375 may include, without limitation, central processing units, graphical processing units, microprocessors, and/or other circuitry that is operable to execute functions associated with control logic.

It will be appreciated that any combination of precursor delivery systems may be incorporated into system 300. For example, system 300 may include one or more gas-phase precursor sources 330, one or more solid-phase precursor sources (each in the form of a remote precursor delivery system), and/or one or more liquid-phase precursor sources (each in the form of a remote precursor delivery system). Vapors of each precursor may be mixed and/or delivered to chambers 305 in any sequence and/or with vapors from different precursors being delivered simultaneously. This may enable a single chamber 305 and/or set of chambers 305 to be used in processing operations that utilize any number of precursors that originate in any number of phases of matter. This may enable faster throughput and may enable processing operations to be performed that require the simultaneous use of vaporized precursors that originate in multiple phases of matter.

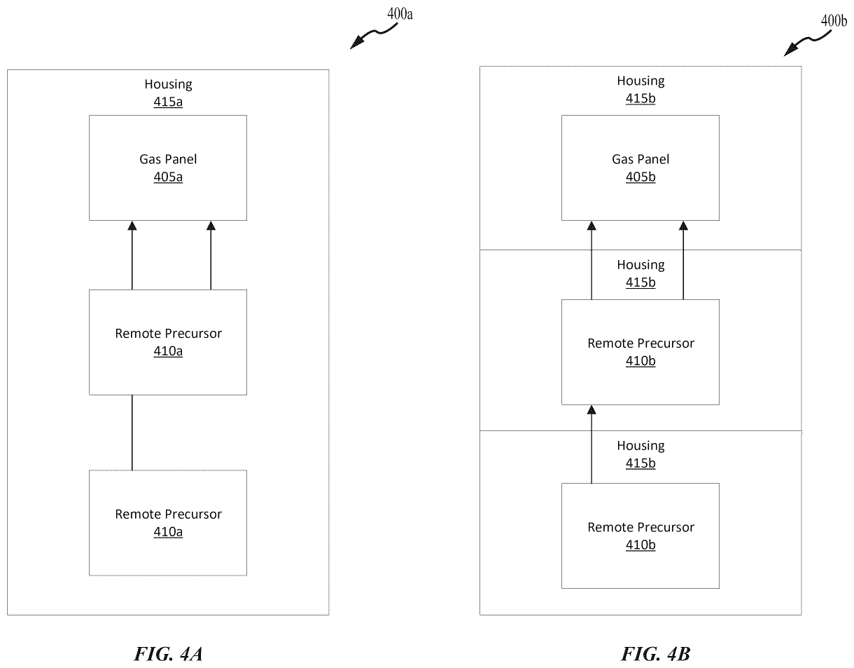

FIGS. 4A and 4B illustrate different embodiments of precursor delivery systems 400 in accordance with the present invention. Systems 400 may be used to deliver vaporized precursors to one or more chambers, such as chambers 200 and 305. Systems 400 may be used as gas panel 325 and remote precursor delivery systems 335 of system 335 and may include any features described in relation to system 300. For example, each system 400 may include at least one gas panel 405 and at least one remote precursor delivery system 410. As illustrated, each system 400 includes a single gas panel 405 and two remote precursor delivery systems 410, although other configurations are possible. For example, each system 400 may include one or more gas panels, two or more gas panels, three or more gas panels, four or more gas panels, five or more gas panels, or more. Each system 400 may include one or more remote precursor delivery systems, two or more remote precursor delivery systems, three or more remote precursor delivery systems, four or more remote precursor delivery systems, five or more remote precursor delivery systems, ten or more remote precursor delivery systems, fifteen or more remote precursor delivery systems, or more.

Each precursor delivery system 400 may include one or more housings 415 that may store the various components of gas panels 405 and/or remote precursor delivery systems 410. For example, as illustrated in FIG. 4A, system 400a includes a single housing 415a that includes all components of system 400a. Housing 415a includes gas panel 405a and two remote precursor delivery systems 410a, which may be stacked vertically and/or arranged horizontally in a side by side manner within housing 415a. In other embodiments, such as shown in FIG. 4B, system 400b may include separate housings 415b for one or more components of system 400b. For example, as illustrated, each component of system 400b includes a dedicated housing 415b, with one housing 415b holding gas panel 405b, and two separate housings 415b each including one of the two remote precursor delivery systems 410b. In some embodiments, housings 415b may be stacked vertically and/or positioned horizontally side by side, with each housing 415b including a number of inlets and outlets that enable fluid lines from components within one housing 415b to be coupled with fluid lines of another housing 415b. For example, delivery lines (such as delivery lines 350) from remote precursor delivery systems 410b may extend through adjacent housings 415b and be coupled with inlets of gas panel 405b that are accessible through the housing 415b that stores gas panel 405. In this manner, any number of gas panels 405b and/or remote precursor delivery systems 410b may be connected to enable the capabilities (e.g., possible chemistry recipes) of system 400b to be easily customized (e.g., components added and/or removed) in a modular fashion.

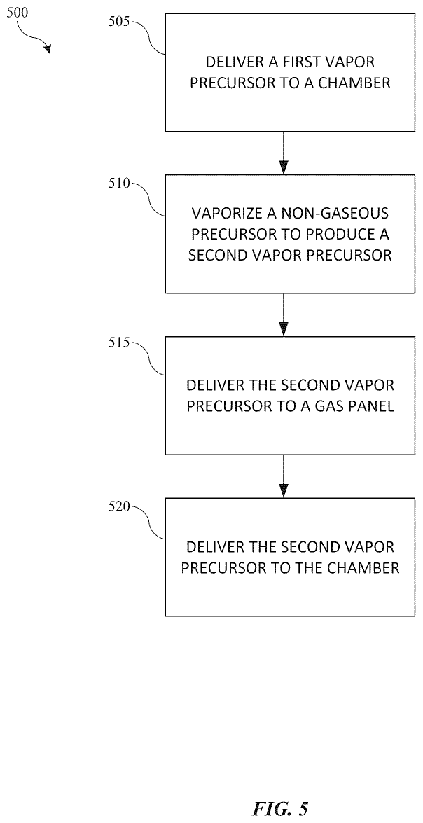

FIG. 5 shows operations of an exemplary method 500 of delivering precursors to a processing chamber according to some embodiments of the present technology. The method may be performed in a variety of processing chambers, including processing chamber 200 and system 300 described above, which may include precursor delivery systems (e.g., gas panels and remote precursor delivery systems) according to embodiments of the present technology, such as gas panels 325 and remote precursor delivery systems 335 and precursor delivery system 400 described herein. Method 500 may include a number of optional operations, which may or may not be specifically associated with some embodiments of methods according to the present technology.

Method 500 may include a processing method that may include operations for forming a hardmask film or other deposition and/or etching operations. The method may include optional operations prior to initiation of method 500, or the method may include additional operations. For example, method 500 may include operations performed in different orders than illustrated. In some embodiments, method 500 may include delivering a first vapor precursor to a processing chamber from a gas panel at operation 505. The first vapor precursor may originate from a vapor precursor source (similar to precursor source 330) or may originate from a non-gaseous precursor source (such as remote precursor delivery system 335). The first vapor precursor may be used to perform a processing operation, such as a deposition or etch operation, on a substrate disposed within a processing region of the chamber. At operation 510, a non-gaseous precursor may be vaporized to generate a second vapor precursor. In some embodiments, the non-gaseous precursor may be a liquid-phase precursor, which may be flowed to a vaporizer via a liquid flow controller of a remote precursor delivery system. The vaporizer may apply heat, pressure, a pressurized carrier gas, and/or vibration to the liquid to generate the second vapor precursor. In some embodiments, the non-gaseous precursor may be a solid-phase precursor. A remote precursor delivery system may apply heat and/or pressure to the solid-phase to generate a vapor via sublimation and/or melting/evaporation.

The second vapor precursor may be delivered to the gas panel from the remote precursor delivery system at operation 515. For example, upon being generated from the non-gaseous precursor, the second vapor precursor may be flowed to the gas panel via one or more delivery lines. In some embodiments, the delivery lines may be heated using a heater and/or heating jackets. At operation 520, the second vapor precursor may be delivered to the processing chamber from the gas panel. For example, the second vapor precursor may be flowed through one or more valves of the gas panel that control flow to the chamber. Flowing the vapor precursors to the chamber may include flowing the precursors directly to a gas distribution assembly of the chamber and/or indirectly via one or more components, such as a remote plasma unit and/or output manifold. The second vapor precursor may be used to perform a processing operation, such as a deposition or etch operation, on a substrate disposed within a processing region of the chamber. The first vapor precursor and the non-gaseous precursor are in different phases of matter. For example, the first vapor precursor may originally be in a gaseous form, while the non-gaseous precursor may originally be in a solid-phase or a liquid-phase.

In some embodiments, the first vapor precursor and the second vapor precursor may be delivered to the processing chamber sequentially and may be used to perform different processing operations of a same or different type (e.g., deposition, etching, etc.). In some embodiments, the first vapor precursor and the second vapor precursor may be delivered to the processing chamber simultaneously and may be mixed together in the gas panel to perform a single processing operation. The first vapor precursor and the second vapor precursor may be delivered to the processing chamber in any order, such as with the first vapor precursor being delivered before or after the second vapor precursor.

In some embodiments, the method may operate in a feedback loop to ensure that a proper flow rate and/or concentration of the second vapor precursor may be delivered to the gas panel and chamber. For example, each remote precursor delivery system may include one or more sensors, such as flow sensors and/or concentration sensors that may be used to determine a flow rate and/or concentration of the second vapor precursor generated from the non-gaseous precursor. In such embodiments, a controller may receive measurements from the various sensors and use the data to adjust one or more parameters of the remote precursor delivery system. For example, for a solid-phase precursor, the controller may adjust a temperature and/or a pressure applied to the solid-phase precursor based on the concentration of the second vapor precursor. For example, a higher temperature and/or pressure may increase the rate of vaporization of the solid-phase precursor, while lowering the temperature and/or pressure may slow the rate of vaporization. Similarly, for a liquid-phase precursor, the controller may adjust a temperature, carrier gas flow rate, vibration rate, and/or a pressure of the liquid and/or a liquid vaporizer based on the concentration and/or flow rate of the second vapor precursor.

In some embodiments, method 500 may include vaporizing an additional non-gaseous precursor to generate a third vapor precursor. The third vapor precursor may be delivered to the gas panel from a second remote precursor delivery system. The third vapor precursor may be delivered to the processing chamber from the gas panel. In some embodiments, the first, second, and third vapor precursors may all originate from precursor sources in different phases of matter. For example, the first, second, and third vapor precursors may include a gas-phase precursor, a liquid-phase precursor, and a solid-phase precursor. In other embodiments, two or more of the vapor precursors may have a same original phase of matter at the respective precursor source. Any number of permutations and any number of precursor may be possible in various embodiments.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
at least one processing chamber, each of the at least one processing chamber comprising a gas distribution assembly;
a gas panel that is fluidly coupled with each gas distribution assembly; and
a remote precursor delivery system that is fluidly coupled with the gas panel, the remote precursor delivery system comprising:
a precursor source associated with a non-gaseous precursor, the precursor source being operable to generate a vapor from the non-gaseous precursor; and
a flow controller that is operable to control a flow of the vapor to the gas panel.

2. The semiconductor processing system of claim 1, wherein:
the remote precursor delivery system comprises a first remote precursor delivery system;
the precursor source of the first remote precursor delivery system comprises a solid-phase precursor source;
the semiconductor processing system further comprises a second remote precursor delivery system that is fluidly coupled with the gas panel, the second remote precursor delivery system comprising:
a precursor source associated with a liquid precursor, the precursor source of the second remote precursor delivery system being operable to generate a vapor from the liquid precursor; and
a flow controller that is operable to control a flow of the vapor from the liquid precursor to the gas panel.

3. The semiconductor processing system of claim 1, wherein:
the remote precursor delivery system comprises a concentration sensor that is operable to determine a concentration of the vapor being delivered to the gas panel; and
the remote precursor delivery system comprises a controller that is operable to adjust one or both of a temperature and a pressure of the non-gaseous precursor based on the 30 concentration of the vapor.

4. The semiconductor processing system of claim 1, wherein:
the precursor source of the remote precursor delivery system comprises a liquid-phase precursor source; and
the remote precursor delivery system comprises:
a liquid flow controller that is fluidly coupled with the liquid-phase precursor source; and
a liquid vaporizer fluidly coupled with a downstream end of the liquid flow controller.

5. The semiconductor processing system of claim 1, further comprising:
one or more heated delivery lines that fluidly couple the remote precursor delivery system with the gas panel.

6. The semiconductor processing system of claim 1, further comprising:
one or more purge lines that fluidly couple the remote precursor delivery system with the gas panel.

7. The semiconductor processing system of claim 1, wherein:
each gas distribution assembly comprises an output manifold; and
the gas panel is fluidly coupled with each gas distribution assembly via a 48 respective one of the output manifolds.

8. The semiconductor processing system of claim 1, further comprising:
a remote plasma unit coupled with each gas distribution assembly, wherein the gas panel is fluidly coupled with each gas distribution assembly via the remote plasma unit.

9. A precursor delivery system, comprising:
a gas panel that is operable to control delivery of one or more precursors to a substrate processing system; and
a remote precursor delivery system that is fluidly coupled with the gas panel, the remote precursor delivery system comprising:
a precursor source associated with a non-gaseous precursor, the precursor source being operable to generate a vapor from the non-gaseous precursor; and
a flow controller that is operable to control a flow of the vapor to the gas panel.

10. The precursor delivery system of claim 9, wherein:
the remote precursor delivery system comprises a first remote precursor delivery system;
the precursor source of the first remote precursor delivery system comprises a solid-phase precursor source;
the precursor delivery system further comprises a second remote precursor delivery system that is fluidly coupled with the gas panel, the second remote precursor delivery system comprising:
a precursor source associated with a liquid precursor, the precursor source of the second remote precursor delivery system being operable to generate a vapor from the liquid precursor; and
a flow controller that is operable to control a flow of the vapor from the liquid precursor to the gas panel.

11. The precursor delivery system of claim 10, wherein:
the first remote precursor delivery system, the second remote precursor delivery system, and the gas panel are disposed within a same housing.

12. The precursor delivery system of claim 9, wherein:
the remote precursor delivery system and the gas panel are disposed within different housings.

13. The precursor delivery system of claim 9, further comprising:
a controller that is operable to control a concentration and flow rate of the vapor.

14. A method for delivering precursors to a processing chamber, comprising:
delivering a first vapor precursor to a processing chamber from a gas panel;
vaporizing a non-gaseous precursor to generate a second vapor precursor;
delivering the second vapor precursor to the gas panel from a remote precursor delivery system; and
delivering the second vapor precursor to the processing chamber from the gas panel, wherein a source of the first vapor precursor and the non-gaseous precursor are in different phases of matter.

15. The method for delivering precursors to a processing chamber of claim 14, further comprising:
heating the second vapor precursor prior to delivering the second vapor precursor to the gas panel.

16. The method for delivering precursors to a processing chamber of claim 14, further comprising:
determining a concentration of the second vapor precursor being delivered to the gas panel; and
adjusting one or both of a temperature and a pressure of the non-gaseous precursor based on the concentration of the second vapor precursor.

17. The method for delivering precursors to a processing chamber of claim 14, wherein:
the remote precursor delivery system comprises a first remote precursor delivery system;
the non-gaseous precursor comprises a liquid precursor; and
the method further comprises:
vaporizing a solid precursor to generate a third vapor precursor;
delivering the third vapor precursor to the gas panel from a second remote precursor delivery system; and
delivering the third vapor precursor to the processing chamber from the gas panel.

18. The method for delivering precursors to a processing chamber of claim 14, wherein:
the first vapor precursor is delivered to the processing chamber after the second vapor precursor.

19. The method for delivering precursors to a processing chamber of claim 14, wherein:
the first vapor precursor and the second vapor precursor are delivered to the processing chamber sequentially.

20. The method for delivering precursors to a processing chamber of claim 14, wherein:
the first vapor precursor and the second vapor precursor are delivered to the processing chamber simultaneously.
